(19) United States
(12) Patent Application Publication
(10) Pub. No.: US 2012/0268283 A1
(43) Pub. Date: Oct. 25, 2012

(54) CIRCUIT BOARD HAVING CURRENT BALANCE FUNCTION

(75) Inventors: SHOU-KUO HSU, Tu-Cheng (TW); YUNG-CHIEH CHEN, Tu-Cheng (TW); HSIEN-CHUAN LIANG, Tu-Cheng (TW); SHEN-CHUN LI, Tu-Cheng (TW); WEN-LAING TSENG, Tu-Cheng (TW); CHIA-NAN PAI, Tu-Cheng (TW)

(73) Assignee: HON HAI PRECISION INDUSTRY CO., LTD., Tu-Cheng (TW)

(21) Appl. No.: 13/167,719

(22) Filed: Jun. 24, 2011

(30) Foreign Application Priority Data
Apr. 22, 2011 (TW) 100114078

(51) Int. Cl. G08B 21/00; G01R 17/02

(52) U.S. Cl. 340/653; 324/98

(57) ABSTRACT

A circuit board includes a current balancing unit that receives a number of current values from ammeters. A minimum current value between the current values is determined by the current balancing unit. Resistance of one or more variable resistors of the current balancing unit is adjusted by the current balancing unit to make the current value from one or more the ammeters serially connected to the one or more the variable resistors to be substantially equal to the minimum current value.

### BACKGROUND

1. Technical Field

The present disclosure relates to circuit boards.

2. Description of Related Art

A circuit board typically includes circuit(s) and connector(s) for connecting external load(s) to the circuit(s). When the external load(s) is(are) connected to the connector(s) and current flows through the circuit(s), the connector(s) in each path may be unbalanced. Accordingly, heat generated from the circuit(s) and the connector(s) may result in partial overheating of the circuit board.

Therefore, a circuit board which can overcome the above limitations is needed.

### BRIEF DESCRIPTION OF THE DRAWINGS

FIG. 1 is a schematic view of a circuit board, according to a first embodiment, showing the circuit board connected to a number of external loads.

FIG. 2 is a schematic view of a circuit board, according to a second embodiment, showing the circuit board connected to a number of external loads.

FIG. 3 is a schematic view of a circuit board, according to a third embodiment, showing the circuit board connected to a number of external loads.

### DETAILED DESCRIPTION

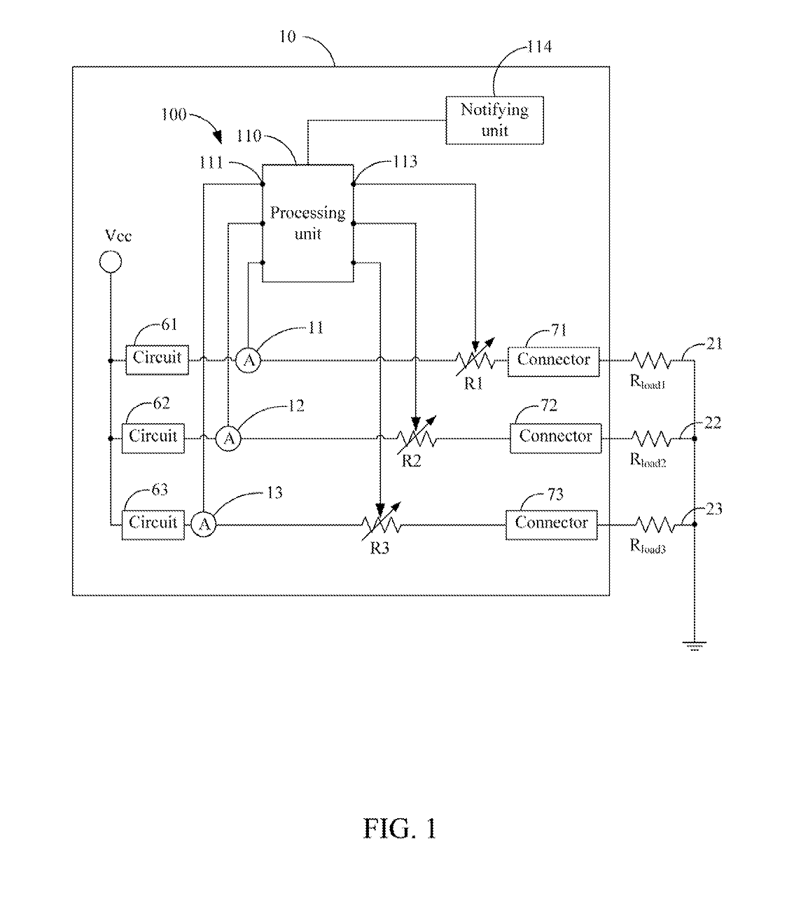

Referring to FIG. 1, a circuit board 10, according to a first embodiment, includes a first circuit 61, a second circuit 62, and a third circuit 63, a first connector 71, a second connector 72, a third connector 73, and a current balancing unit 100. External loads R_{load1}, R_{load2}, R_{load3} (hereinafter a first load R_{load1}, a second load R_{load2}, and a third load R_{load3}) are respectively connected to the first connector 71, the second connector 72 and the third connector 73. The circuit board 10 further includes a power terminal Vcc for connection to a power supply.

The balancing unit 100 includes a first variable resistor R1, a second variable resistor R2, and a third variable resistor R3, a first ammeter 11, a second ammeter 12, a third ammeter 13, a processing unit 110, and a notifying unit 114.

The first circuit 61, the first ammeter 11, the first variable resistor R1, the first connector 71 and the first load R_{load1} are connected in series in that order to form a first path 21. The second circuit 62, the second ammeter 12, the second variable resistor R2, the second connector 72 and the second load R_{load2} are connected in series in that order to form a second path 22. The third circuit 63, the third ammeter 13, the third variable resistor R3, the third connector 73 and the third load R_{load3} are connected in series in that order to form a third path 23.

The processing unit 110 includes three input terminals 111, and three control terminals 113. The three input terminals 111 are respectively connected to the three ammeters 11, 12, and 13. The three control terminals 113 are respectively connected to the three variable resistors R1, R2 and R3. The processing unit 110 is configured to receive current values from the three ammeters 11, 12 and 13, to determine the lowest current value between the three current values from the three ammeters 11, 12 and 13, to adjust the resistance of the variable resistor(s) R1, R2, or R3 to make the current values which are greater than the lowest current value substantially equal to the lowest current value, and to activate the notifying unit 114 if one or more the variable resistors cannot be adjusted to give a current value substantially equal to the lowest current value received by processing unit 110.

For example, assume that the current from the first ammeter 11 is 1 A, the current from the second ammeter 12 is 1.5 A and the current from the third ammeter 13 is 2.0 A; the processing unit 110 determines the value of the lowest current as 1 A and so increases the resistance of the second variable resistor R2 and the third variable resistor R3 to restrict the current passing through the second and third ammeters 12 and 13 to (substantially) 1 A. However, if the processing unit 110 increases the resistance of the second variable resistor R2 and/or the third variable resistor R3 to their respective limits of resistance and the current value(s) from the resistor R2 and/or the resistor R3 is(are) still greater than 1 A, then the processing unit 110 activates the notifying unit 114 to output notification to the user. It is to be understood that the initial resistance of the resistors R1, R2 and R3 may be equal to zero or may default to zero in operation, this device will balance the amount of current flowing in each path and overheating or partial overheating of the circuit board 10 can be avoided or at least alleviated.

The notifying unit 114 may include a buzzer and/or a flash to emit an audible signal and/or a visual signal to the user.

It is to be noted that in alternative embodiments, the ammeters 11, 12 and 13 and/or the notifying unit 114 may be incorporated with the processing unit 110. The circuit board 10 may include a plurality of circuits, connectors, ammeters, and variable resistors.

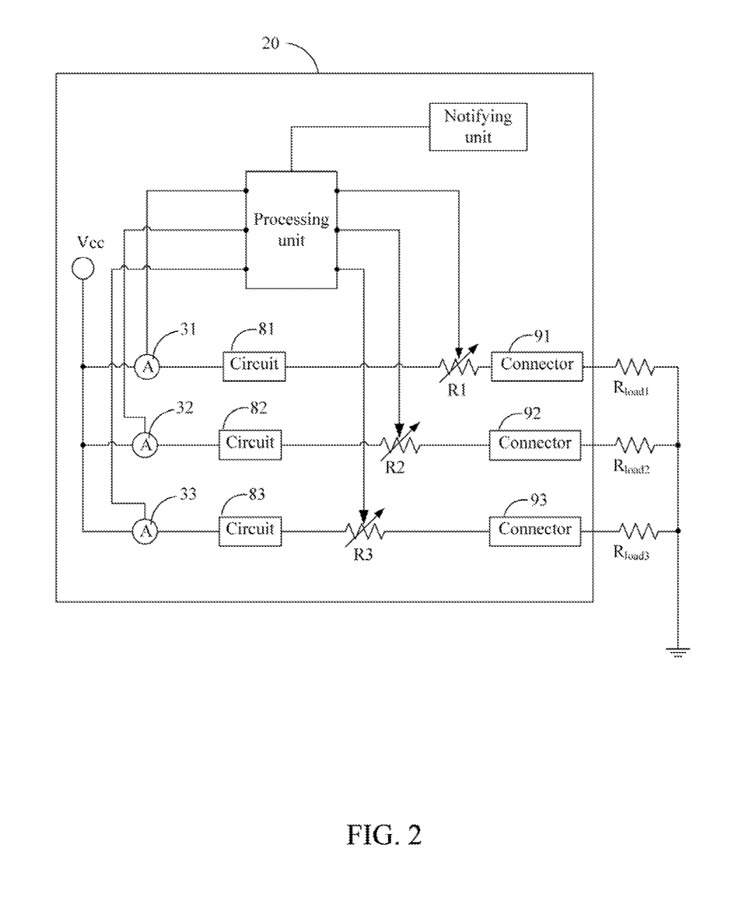

Referring to FIG. 2, a circuit board 20, according to a second embodiment, is shown. The points of difference between the circuit board 20 and the circuit board 10 of the first embodiment are that a first ammeter 31, a first circuit 81, a first variable resistor R1, a first connector 91 and a first load R_{load1} are connected in series in that order; a second ammeter 32, a second circuit 82, a second variable resistor R2, a second connector 92 and a second load R_{load2} are connected in series in that order; a third ammeter 33, a third circuit 83, a third variable resistor R3, a third connector R_{conj3} and a third load 93 are connected in series in that order.

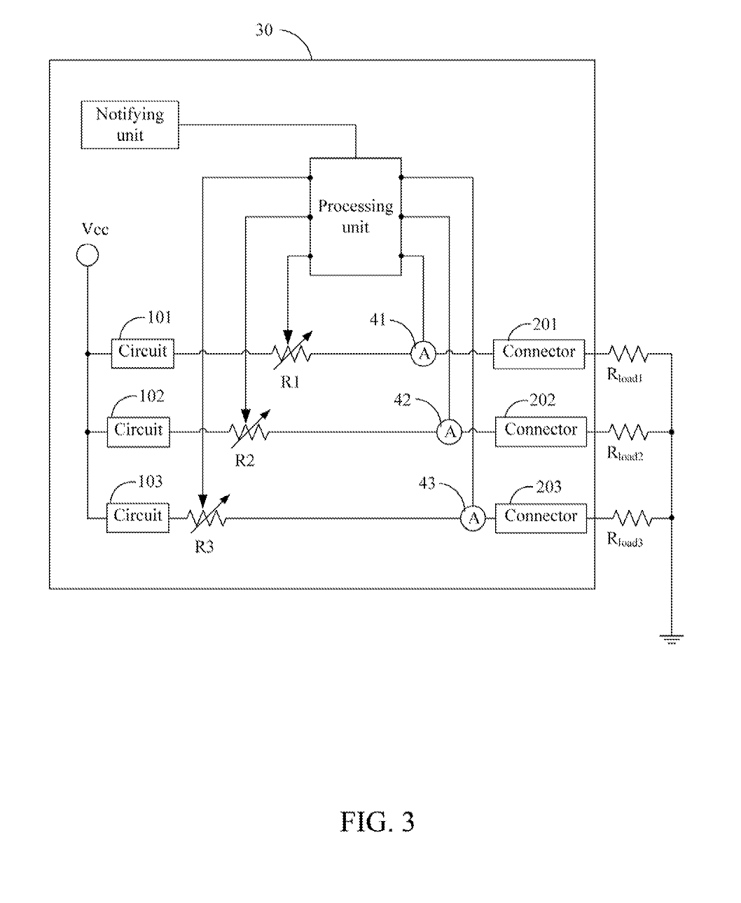

Referring to FIG. 3, a circuit board 30, according to a third embodiment, is shown. The points of difference between the circuit board 30 and the circuit board 10 of the first embodiment are that a first circuit 101, a first variable resistor R1, a first ammeter 41, a first connector 201 and a first load R_{load1} are connected in series in that order; a second circuit 102, a second variable resistor R2, a second ammeter 42, a second connector 202 and a second load R_{load2} are connected in series in that order; a third circuit 103, a third variable resistor R3, a third ammeter 43, a third connector 203 and a third load R_{load3} are connected in series in that order.

It should be noted that in alternative embodiments, the manner and types of connections between the circuits, the ammeters, the variable resistors and the connectors in each path may be changed according to the above-described embodiments.

It is to be understood, however, that even though numerous characteristics and advantages of the present embodiments have been set forth in the foregoing description, together with details of the structures and functions of the embodiments, the disclosure is illustrative only, and changes may be made in detail, especially in matters of shape, size, and arrangement of parts within the principles of the disclosure to the full extent indicated by the broad general meaning of the terms in which the appended claims are expressed.

What is claimed is:

1. A circuit board, comprising:
at least two circuits;
at least two connectors, each of the at least two connectors configured to connect each of the at least two circuits to an external load; and
a current balancing unit comprising at least two ammeters, a processing unit, and at least two variable resistors, each of the at least two circuits, each of the at least two ammeters, each of the at least two variable resistors, and each of the at least two connectors being connected in series, the processing unit connected to the at least two ammeters and the at least two variable resistors and configured to receive current values from the at least two ammeters, and to determine a minimum current value between the current values, and to adjust resistance of one or more of the at least two variable resistors to make the current value from one or more of the at least two ammeters serially connected to the one or more of the at least two variable resistors to be substantially equal to the minimum current value.

2. The circuit board of claim 1, wherein the processing unit comprises at least two input terminals and at least two control terminals, each of the at least two input terminals connected to a corresponding ammeter, each of the at least two control terminals connected to a corresponding variable resistor.

3. The circuit board of claim 1, wherein each of the at least two circuits, each of the at least two ammeters, each of the at least two variable resistors, and each of the at least two connectors are connected in series in that order.

4. The circuit board of claim 1, wherein each of the at least two ammeters, each of the at least two circuits, each of the at least two variable resistors, and each of the at least two connectors are connected in series in that order.

5. The circuit board of claim 1, wherein each of the at least two circuits, each of the at least two variable resistors, each of the at least two ammeters, and each of the at least two connectors are connected in series in that order.

6. The circuit board of claim 1, further comprising a notifying unit, the processing unit configured to activate the notifying unit if the one or more of the least two variable resistors cannot be adjusted to give a current value substantially equal to the minimum current value received by the processing unit.

7. The circuit board of claim 6, wherein the notifying unit comprises a buzzer and/or a flash.

8. A circuit board, comprising:
three circuits;
three connectors, each of the three connectors configured to connect each of the three circuits to an external load; and
a current balancing unit comprising three ammeters, a processing unit, and three variable resistors, each of the three circuits, each of the three ammeters, each of the three variable resistors, and each of the three connectors being connected in series, the processing unit connected to the three ammeters and the three variable resistors and configured to receive current values from the three ammeters, and to determine a minimum current value between the current values and to adjust resistance of one or more of the three variable resistors to make the current value from one or more of the three ammeters serially connected to the one or more of the three variable resistors to be substantially equal to the minimum current value.

9. The circuit board of claim 8, wherein the processing unit comprises three input terminals and three control terminals, each of the three input terminals connected to a corresponding ammeter, each of the three control terminals connected to a corresponding variable resistor.

10. The circuit board of claim 8, wherein each of the three circuits, each of three ammeters, each of the three variable resistors, and each of three connectors are connected in series in that order.

11. The circuit board of claim 8, wherein each of the three ammeters, each of the three circuits, each of the three variable resistors, and each of the three connectors are connected in series in that order.

12. The circuit board of claim 8, wherein each of the three circuits, each of the three variable resistors, each of the three ammeters, and each of the three connectors are connected in series in that order.

13. The circuit board of claim 8, further comprising a notifying unit, the processing unit configured to activate the notifying unit if the one or more of the three variable resistors cannot be adjusted to give a current value substantially equal to the minimum current value received by the processing unit.

14. The circuit board of claim 13, wherein the notifying unit comprises a buzzer and/or a flash.
